(19) United States
(12) Patent Application Publication
(10) Pub. No.: US 2023/0380067 A1
(43) Pub. Date: Nov. 23, 2023

(54) COMPRESSED PINOUTS FOR HIGH-SPEED DIFFERENTIAL PAIRS

(71) Applicant: Intel Corporation, Santa Clara, CA (US)

(72) Inventors: Raul Enriquez Shibayama, Zapopan (MX); Kai Xiao, Portland, OR (US); Carlos Alberto Lizalde Moreno, Guadalajara (MX); Luis E. Rosales Galvan, Portland, OR (US)

(73) Assignee: Intel Corporation, Santa Clara, CA (US)

(21) Appl. No.: 17/750,016

(22) Filed: May 20, 2022

(51) Int. Cl. H05K 1/18

(52) U.S. Cl. CPC H05K 1/181; H05K 2201/10325; H05K 2201/10303; H05K 2201/10704

(57) ABSTRACT

In one embodiment, a package substrate or main circuit board includes electrical connectors arranged in a compressed array pattern, wherein a distance between a connector and its neighboring connectors in a direction of compression is less than a distance between the connector and its neighboring connectors in other directions. The array pattern may be hexagonal or rectangular, and differential pairs of the electrical connectors may be arranged in the direction of compression.

### BACKGROUND

Existing socket designs have uniformly pitched pinouts. For instance, socket designs with square pinout arrangements have pins that are equidistant from its neighboring pins in the x- and y-directions, while socket designs with hexagonal pinout arrangement have pinouts where the pins are equidistant from its neighboring pins in all directions.

### BRIEF DESCRIPTION OF THE DRAWINGS

FIGS. 1A-1B illustrate example systems that may implement a compressed pinout in accordance with embodiments herein.

FIGS. 2A-2B illustrate example compressed hexagonal pinouts in accordance with embodiments herein.

FIG. 3 illustrates example simulation results between a conventional hexagonal pinout and a compressed hexagonal pinout in accordance with embodiments herein.

FIG. 4 illustrates example differential pairs and traces of a circuit board.

FIG. 5A illustrates a circuit board pinout with differential pairs in a minion pinout arrangement in accordance with embodiments herein.

FIGS. 5B-5C illustrate example simulation data for the pinout of FIG. 5A in an uncompressed and compressed arrangement, respectively.

FIGS. 6A-6C illustrate example compressed square (rectangular) pinouts in accordance with embodiments herein.

FIG. 7 is a top view of a wafer and dies that may be included in a microelectronic assembly, in accordance with any of the embodiments disclosed herein.

FIG. 8 is a cross-sectional side view of an integrated circuit device that may be included in a microelectronic assembly, in accordance with any of the embodiments disclosed herein.

FIG. 9 is a block diagram of an example electrical device that may include a microelectronic assembly, in accordance with any of the embodiments disclosed herein.

### DETAILED DESCRIPTION

In embodiments herein, socket pinout arrangements may be “compressed” such that the distance between differential pair pins in the pinout arrangement is less than with conventional pinout arrangements where the differential pair pins have the same distance between them as the space between other pins. For instance, a conventional hexagonal pinout arrangement may implement pins that are equidistant from one another in all directions in certain embodiments herein, a hexagonal pinout arrangement may compress the pin pitch distance in a direction in which differential pair pins are implemented/grouped. This may create a socket pinout of non-uniform pitch in one direction, while keeping the high-speed differential pinout arrangement similar to the existing pinout. Such compression may be applied to patterns that have differential pairs grouped in one direction, e.g., a so-called “minion” pattern with a signal-to-ground ratio (S/G) of 1:1.5 (i.e. for one signal pin, there may be 1.5 ground pins), a so-called “twinax” pattern with at S/G ratio of 1:2, etc. (i.e. for one signal pin, there may be 2 ground pins), and are able to meet the Peripheral Component Interconnect Express (PCIe) electrical performance requirements (e.g., those for PCIe 6.0 or beyond). Embodiments herein may accordingly provide new and efficient socket pin patterns and pinout arrangements that may meet the required electrical performance at the component level, maximize a through-socket I/O bandwidth density, and deliver performance/cost-optimized package, socket, and platform solutions.

In some cases, it may be desirable to add pins to a socket, e.g., to add certain features to the socket design. However, adding pins will grow the size/form factor of the socket and package, potentially adding significant product cost or causing many other issues, such as platform fit, mechanical challenges of loading the socket, board manufacturing, reliability, etc. In some instances, adding pins is not an available solution, and as such, features may be limited or trade-offs may be needed, such as limiting number of I/O ports & lanes, which can have a big impact on the product performance.

For example, certain embodiments may provide more socket pins within the same form factor as existing designs. Comparing to conventional differential pinouts of a hexagonal array socket, which may have a 37 mils uniform pitch, compressing the pinout in one direction to, e.g., 33 mils, a pin count increase of approximately 10% may be seen without growing the socket form factor. In certain cases, this could lead to fitting up to 48 (or more) additional differential pairs to an existing form factor. Additionally, cost savings may be seen with embodiments herein, as the size of the socket and package must grow to implement additional pins, which can incur a very significant product cost adder. Embodiments herein may also provide similar or even better electrical performance to conventional pinout designs. Since the compression described herein is in the direction of differential pin pair grouping, the differential pin pairs may be more closely coupled, potentially helping to lower the differential impedance and reduce crosstalk. In addition, the straightforward signal breakout may make the board layout easier, and may improve link performance by eliminating the non-preferred trace-to-via coupling cases (e.g., for breakout traces from a via farm under the socket on the motherboard).

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

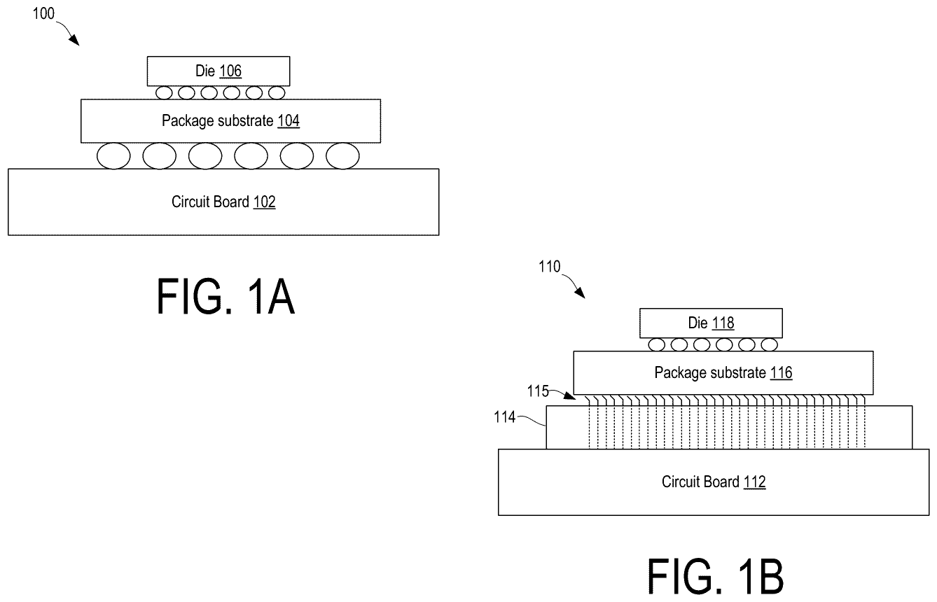

FIGS. 1A-1B illustrate example systems 100, 110 that may implement a compressed pinout in accordance with embodiments herein. The example system 100 of FIG. 1A includes a circuit board 102, which may be implemented as a motherboard or main board of a computer system in some embodiments, or as a base circuit board of a peripheral device (e.g., a graphics card, non-volatile memory PCIe device, etc.) that is to be connected to another circuit board (e.g., a motherboard of a computer system). The example system 100 also includes a package substrate 104 with an integrated circuit die 106 attached to the package substrate 104.

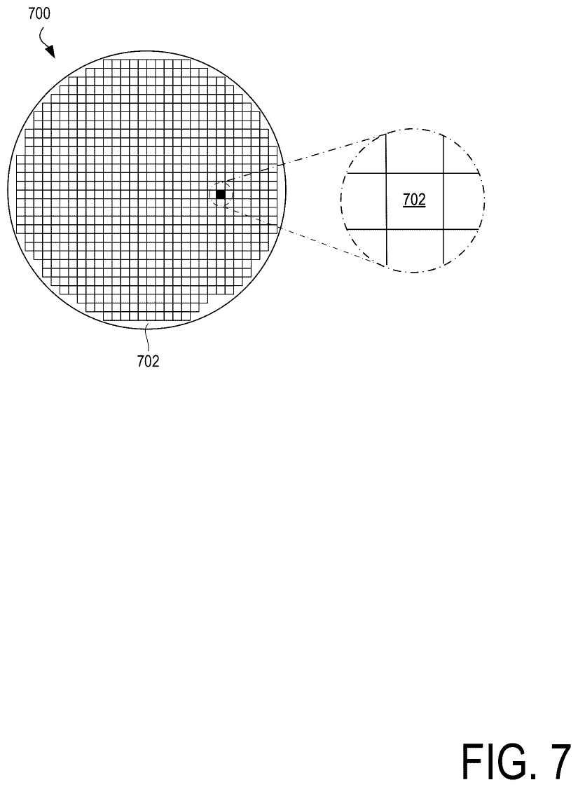

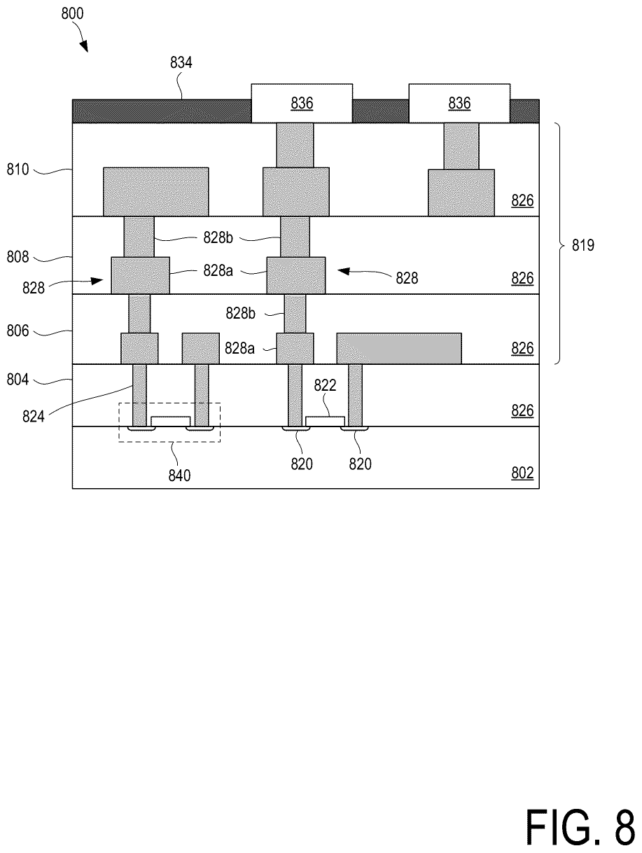

The die 106 may be a packaged or unpacked integrated circuit product that includes one or more integrated circuit dies (e.g., the die 702 of FIG. 7, the integrated circuit device 800 of FIG. 8) and/or one or more other suitable components. The die 106 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the die 106 can comprise one or more additional active or passive devices such as capacitors, decoupling capacitors, resistors, inductors, fuses, diodes, transformers, sensors, electrostatic discharge (ESD) devices, and memory devices. In addition to comprising one or more processor units, the die 106 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”.

The package substrate 104 may provide electrical connections between the die 106 and the circuit board 102. In addition, in embodiments where the die 106 includes multiple integrated circuits/dies, interconnections between dies can be provided by the package substrate 104, one or more silicon interposers, one or more silicon bridges embedded in the package substrate (such as Intel® embedded multi-die interconnect bridges (EMIBs)), or combinations thereof.

Similar to the system 100, the system 110 also includes a circuit board 112 with a package substrate 116 (having an attached integrated circuit die 118) attached to the circuit board 112. The package substrate 116 may be implemented in the same or similar manner as the package substrate 104, and the integrated circuit die 118 may be implemented in the same or similar manner as the die 106. The system 110 also includes a socket 114 that provides an interconnection between the package substrate 116 and the circuit board 112 via pins 115. In the example shown, the pins 115 are implemented as a cantilever design; however, the pins 115 may be implemented in another manner, e.g., as a spring interposer design.

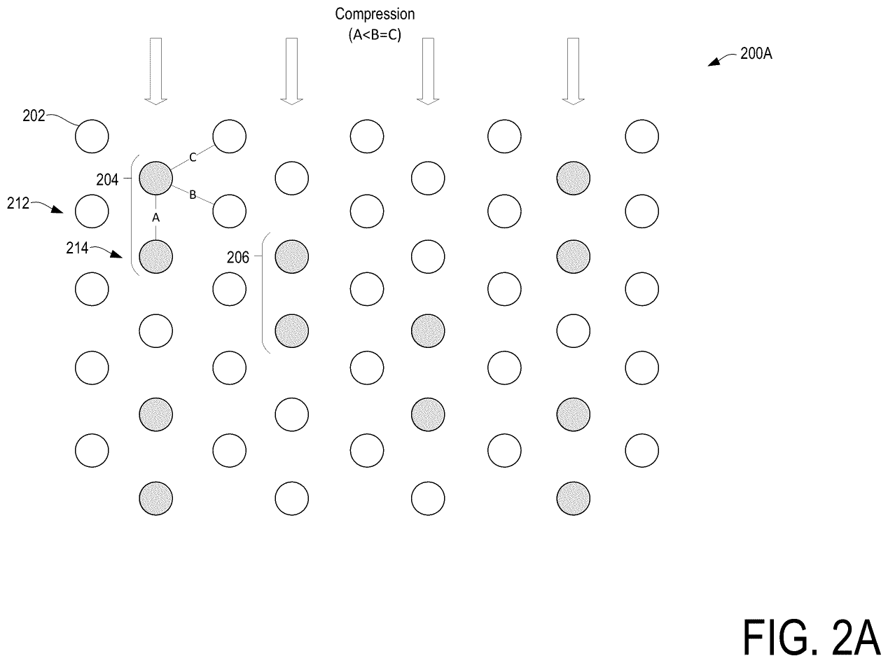

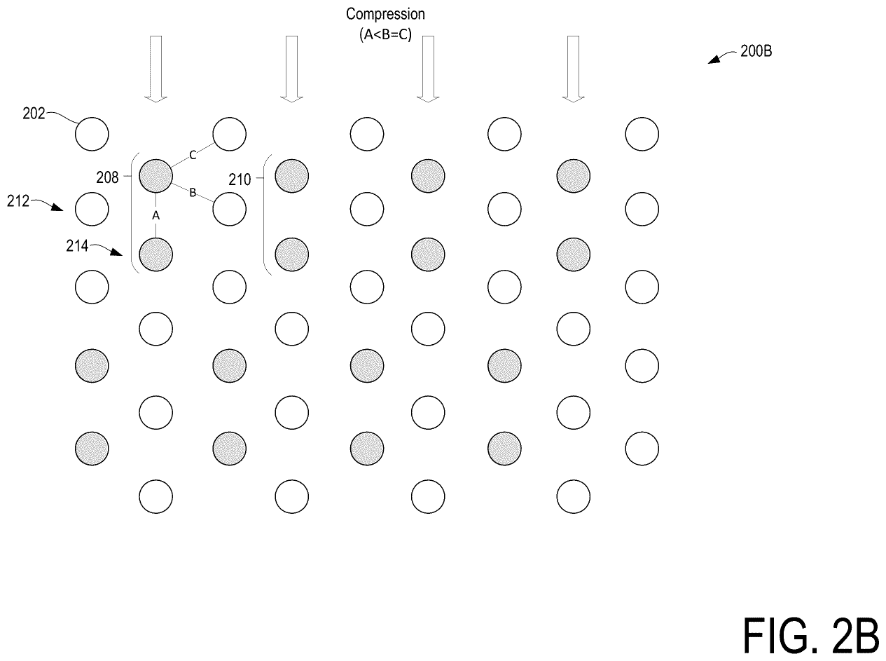

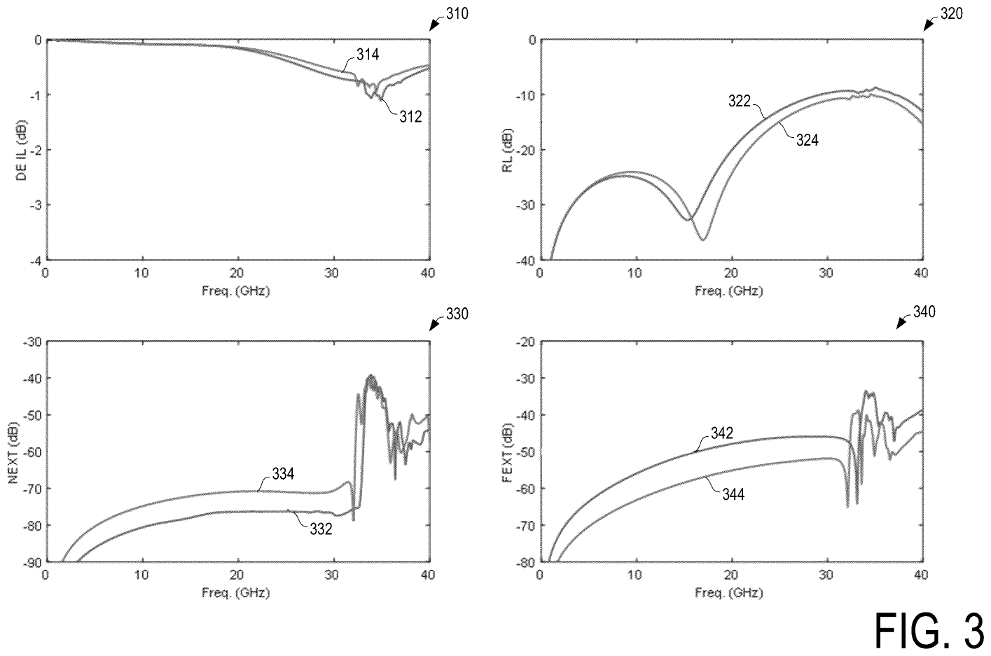

In either system 100, 110, the pinout arrangement for the connections between the package substrate 104, 116 and the circuit board 102, 112 may be implemented as a compressed pinout arrangement as described herein. Example pinout arrangement are described further below. The pinouts shown in FIGS. 2A-2B, 3A-3B may be implemented on the bottom side of the package substrate 104 and the top side of the circuit board 102 of FIG. 1A or on the bottom side of the package substrate 116 and the top side of the circuit board 112 of FIG. 1B (as well as in the socket 114 and the pins 115 therein).

FIGS. 2A-2B illustrate example compressed hexagonal pinouts 200 in accordance with embodiments herein. In each example, there are a plurality of pins 202 in a hexagonal array pattern, in which each pin has a hexagonal pattern of neighboring pins surrounding it. The hexagonal pattern may be an array of pins arranged in rows and columns with alternating rows being offset from one another. For instance, in the examples shown, the pins 202 of row 212 are offset in their alignment from the pins of row 214.

In conventional pinout arrangements, the distance between the pins may be the same as one another. For instance, referring to the examples shown in FIGS. 2A-2B, the distances A, B, and C may be equal to one another in conventional pinout arrangements. However, in embodiments herein, the pinout arrangements are compressed in the direction of differential pairs (e.g., 204, 206) of the pinout (in the vertical direction as shown in FIGS. 2A-2B), causing the distance A to be less than B and C. That is, the distance between a pin and its neighboring pin in the vertical direction (in the example shown) is less than a distance between the pin and its other neighboring connectors in the hexagonal pattern around it.

This compression has the effect of reducing the distance/pitch between the differential pair pins. In some cases, the compression of the A dimension may be limited by the PCB technology used for the circuit board on which the pinout is implemented. For instance, with current PCB Design for Manufacturing (DFM) rules, after applying anti-pads of the minimum size to the board via design, the webbing connection on the reference plane may be lost if too small a pitch is used. In some instances, this limit may be approximately 33 mils. Thus, in some embodiments, the measurement of A may be approximately 33 mils, while the measurement for B and C may be approximately 37 mils. However, in other instances, the measurement of A may be less than 33 mils, with the measurement for B and C still being approximately 37 mils.

In the examples shown, certain pin pairs making up a differential pair (e.g., 204, 206). The pins 202 may be electrical connectors located on the bottom side (i.e., the side opposite a side of the substrate on which a die is attached) of a package substrate (e.g., 104, 116), on the top of a circuit board (e.g., 102, 112), or in a socket (e.g., 114) between a package substrate and a circuit board. The example pinout pattern shown in FIG. 2A is a compressed twinax pattern, wherein the pins of the differential pairs are 2 pins away from one another (e.g., the bottom pin of 204 is two pins away from the bottom pin of 206). In contrast, the pinout pattern shown in FIG. 2B is a compressed “minion” pattern, wherein the pins of the differential pairs are 1.5 pins away from each other (e.g., the bottom pin of 208 is 1.5 pins away from the bottom pin of 210).

FIG. 3 illustrates example simulation results between a conventional hexagonal pinout and a compressed hexagonal pinout in accordance with embodiments herein. In particular, the simulation results shown in FIG. 3 model a minion pattern, such as that shown in FIGS. 2A-2B. The plots 310, 320, 330, 340 represent example data for insertion loss, return loss, far-end crosstalk, and near-end crosstalk results, respectively, with the curves 312, 322, 332, 342 representing the data for the uncompressed pattern and the curves 314, 324, 334, 344 representing the data for the compressed pattern. These example results show that the compressed minion pattern is similar in performance in insertion loss, while being ˜10 dB better in the far-end crosstalk comparison, and slightly better in the high frequency range for return loss. This is likely because the compression of the intra-pair pitch increases the coupling between the two pins in a differential pair, lowering the impedance and reducing the coupling between adjacent pairs. Because the socket pins typically tend to have higher impedance, lowering the impedance may help improve the impedance matching. The results also show a ˜5 dB increase in the near-end crosstalk for the compressed pattern; however, the absolute crosstalk level is still below −70 dB and therefore, the difference from the absolute coupling strength point of view may be considered negligible.

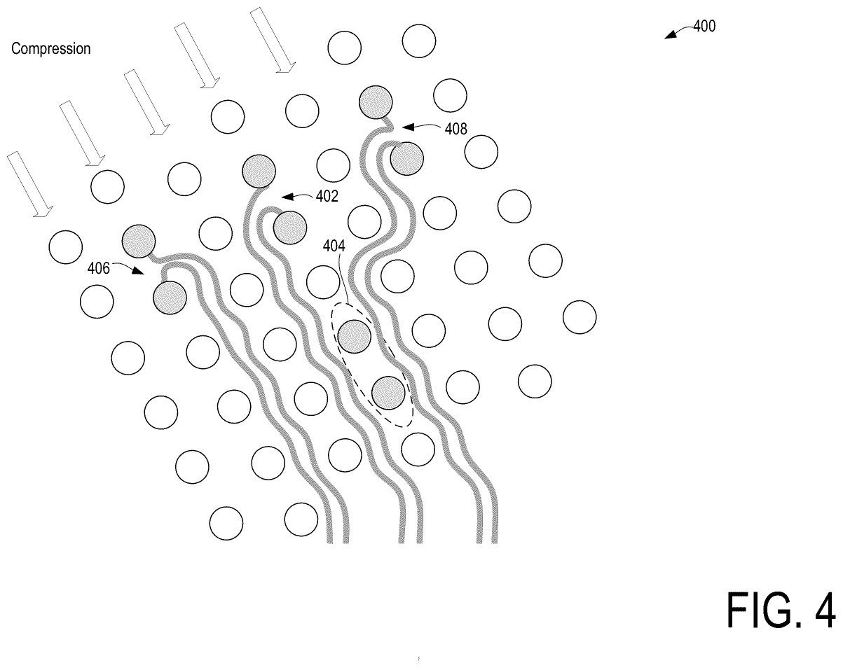

In the socket pinfield, the impedance of the traces, and the related trace-to-via coupling when high-speed signals are breaking out through the pinfield, have a significant impact to the link performance. FIG. 4 illustrates example differential pairs and traces of a circuit board that were modeled for a compressed arrangement and an uncompressed arrangement, and Table 1 below shows the results of the modeling. In the example shown, the trace pair 402 represents the DUT pair, the (circled) via pair 404 are the near-end crosstalk (NEXT) signal pair, and the trace pairs 406, 408 are the far-end crosstalk signal (FEXT) pairs.

TABLE 1

| | Insertion loss | Return loss | FEXT (406) | FEXT (408) | NEXT (402) |
|---|---|---|---|---|---|
| Pattern | @ 16 GHz | @ 16 GHz | @ 16 GHz | @ 16 GHz | @ 16 GHz |
| Uncompressed | −0.61 dB | −12.3 dB | −43.3 dB | −45.6 dB | −48.5 dB |
| Compressed | −0.54 dB | −13.5 dB | −49.7 dB | −51.9 dB | −52.2 dB |

As shown, a compressed pinout arrangement as described herein provides lower crosstalk when compared with the conventional uncompressed pinout arrangement.

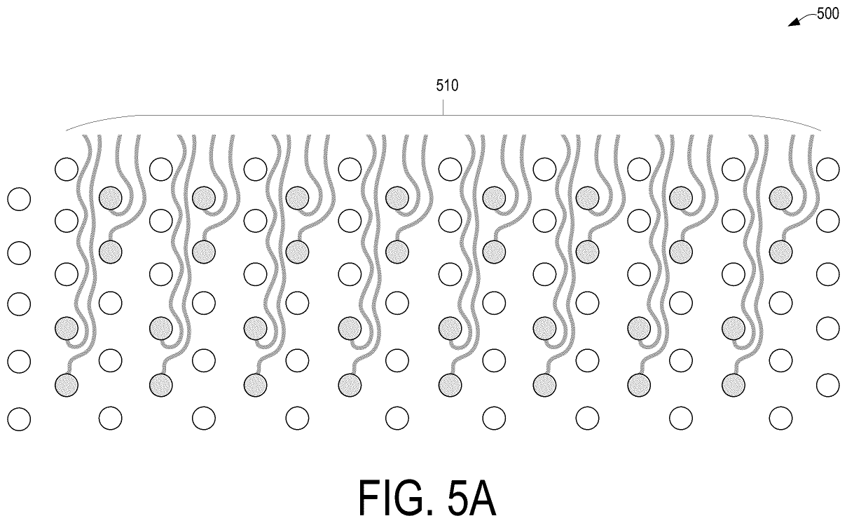

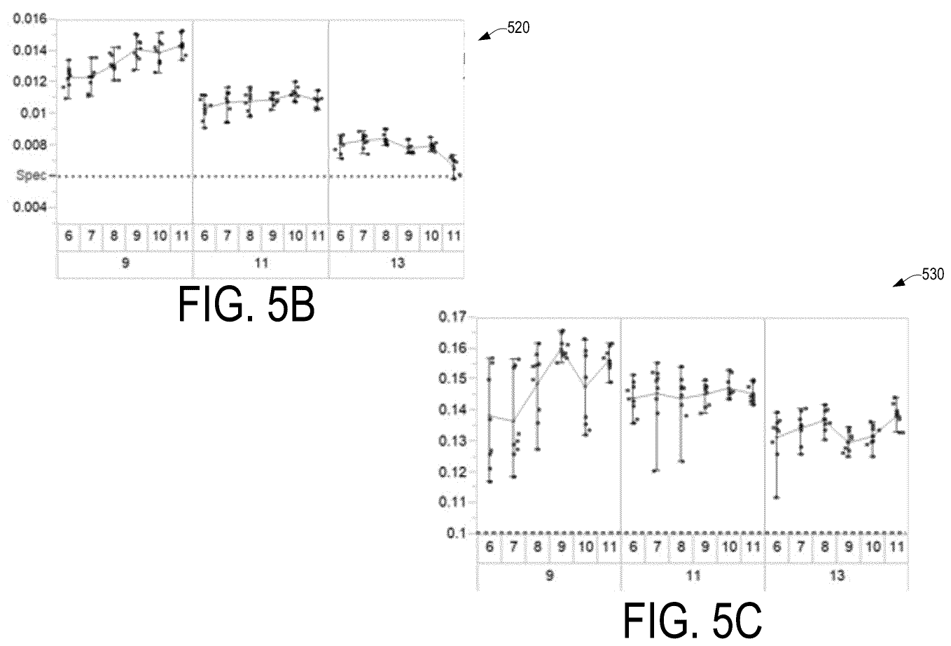

FIG. 5A illustrates a circuit board pinout 500 with differential pairs in a compressed minion pinout arrangement in accordance with embodiments herein. As shown in FIG. 5, the compressed minion pattern allows for the grouping of 16 pairs of a Peripheral Component Interconnect Express (PCIe) x16 port in two rows of the pin pairs, with the 16 pairs being allowed to break out on the same layer of the motherboard. This may be an important advantage over a traditional ‘trapezoidal’ pattern (DROP), in which all 16 pairs need to be arranged in the same row to break out on the same layer to limit the board layer count. That is, with the trapezoidal pattern, the differential pinout will be much wider and push a memory pin area to be narrower. As a result, some bytes of the memory channels may need to be moved deeper into the socket center area, causing breakout and performance challenges. From a global pinout arrangement point of view, the compressed ‘minion pattern’ as described herein can therefore provide both pinout flexibility and pin density.

A full link analysis was performed based on a PCIe 6.0, 1-connector topology, with FIGS. 5B-5C illustrating the resulting data 520, 530 for the pinout of FIG. 5A in an uncompressed and compressed arrangement, respectively. As shown in the plot 520 of FIG. 5B, with the conventional uncompressed minion pattern, the maximum PCIe channel reach that can be supported (based on assumptions of the analysis) is approximately 13″. However, as shown in plot 530 of FIG. 5C, with the compressed minion pattern as described herein, under the same analysis assumptions as in FIG. 5A, a solution space of 13″ is achievable with ˜1 mV margin. Thus, the compressed minion is at least on par with the traditional pinout in term of performance at full-link level.

While the above describes compressed hexagonal pinout patterns, such as the compressed minion pattern, the compression concepts may also apply to other types of arrangements as well.

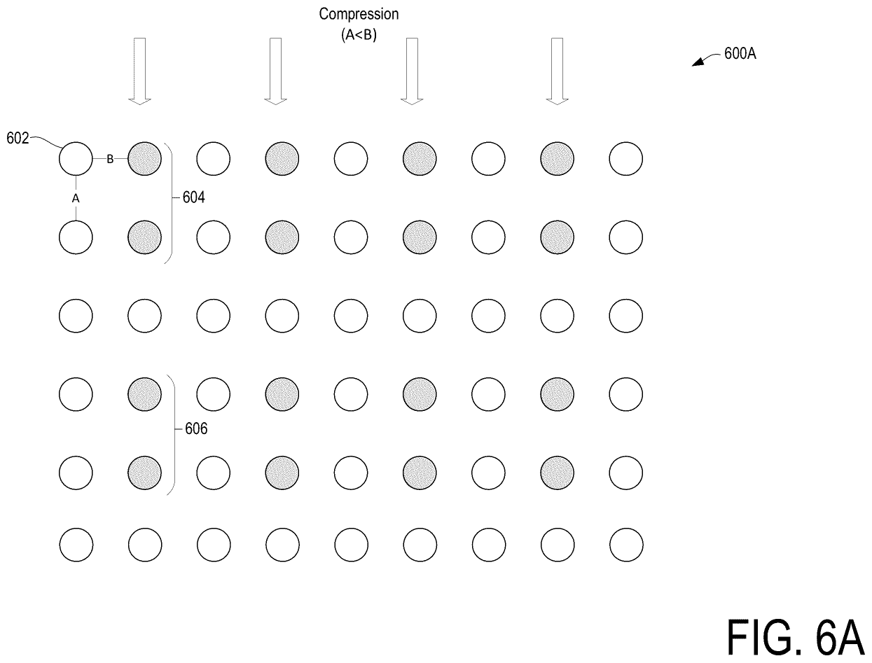

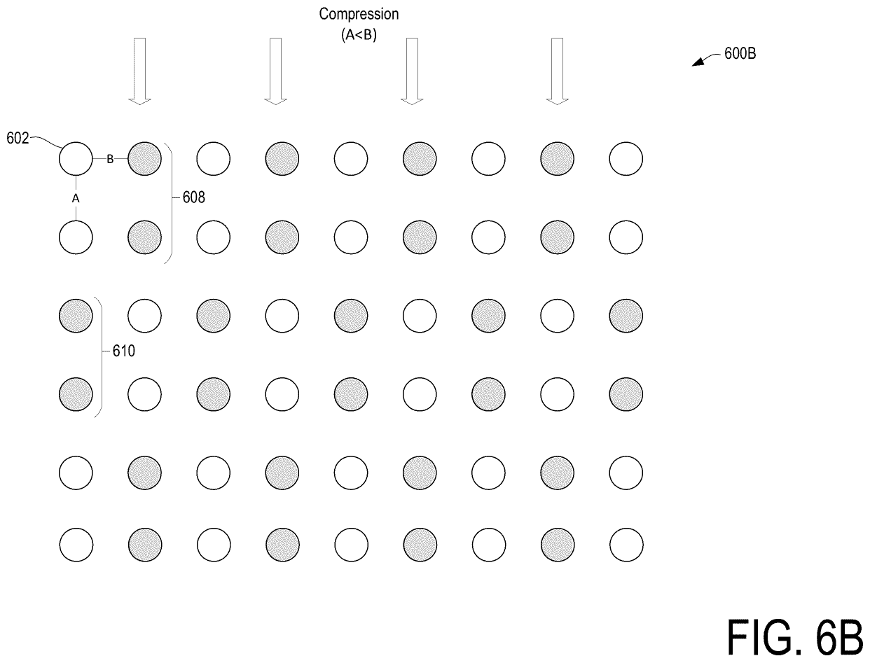

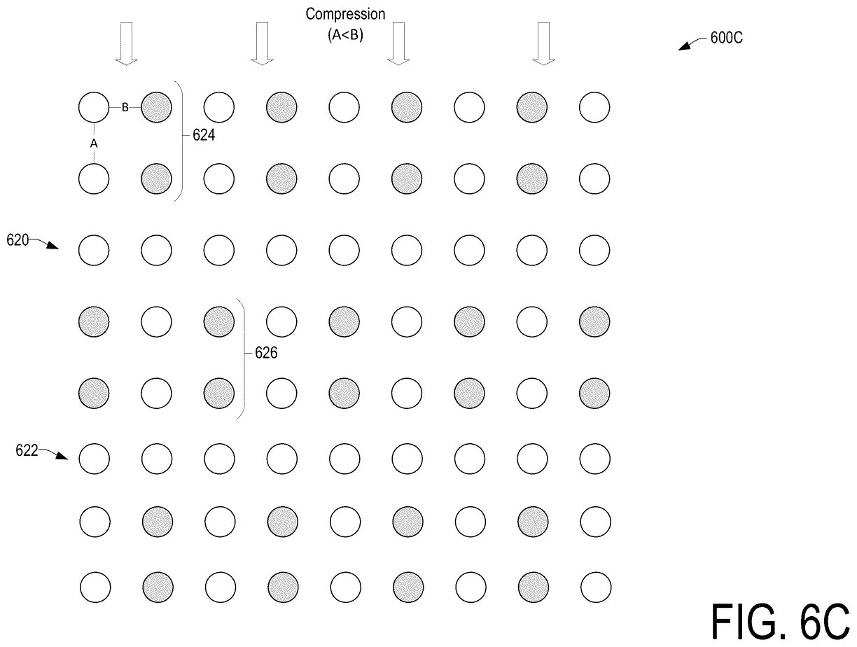

FIGS. 6A-6C illustrate example compressed square (rectangular) pinouts 600A, 600B, 600C in accordance with embodiments herein. In each example of FIGS. 6A-6C, there are a plurality of pins 602 in a rectangular array pattern, with certain pin pairs making up a differential pair (e.g., 604, 606). The pins 602 may be implemented similar to the pins 202 of FIGS. 2A-2B. In the examples shown, the pins 602 are arranged in rows and columns, where the rows and columns are aligned with one another (in contrast to the hexagonal patterns shown in FIGS. 2A-2B).

In conventional square pinout arrangements, the distance between the pins in each row and the distance between the pins in each column may be the same. For instance, referring to the examples shown in FIGS. 6A-6C, the distances A and B may be equal to one another in conventional pinout arrangements. However, in embodiments herein, the pinout arrangements are compressed in the direction of differential pairs (e.g., 604, 606) of the pinout (in the vertical direction as shown in FIGS. 6A-6C), causing the distance A to be less than B. That is, the distance between a pin and its neighboring pin in the vertical direction is less than a distance between the pin and its other neighboring connectors in its row and column.

The example pinout pattern shown in FIG. 6A is a compressed twinax pattern, wherein the pins of the differential pairs are 2 pins away from one another (e.g., the bottom pin of 604 is two pins away from the top pin of 606). In contrast, the pinout pattern shown in FIG. 6B is a compressed offset twinax pattern, wherein the pins of the differential pairs are 1.5 pins away from each other (e.g., the bottom pin of 608 is 1.5 pins away from the top pin of 610). The pinout pattern shown in FIG. 6C is similar to the compressed offset twinax pattern of FIG. 6B, but with ad additional row of ground pins (e.g., 620, 622) separating the sets of differential pairs (e.g., 624, 626).

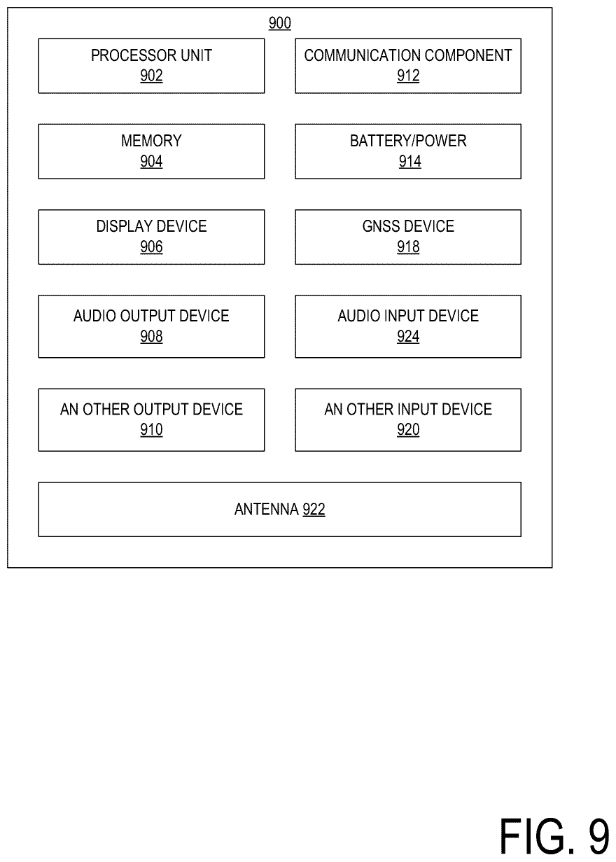

FIG. 7 is a top view of a wafer 700 and dies 702 that may be implemented in or along with any of the embodiments disclosed herein. The wafer 700 may be composed of semiconductor material and may include one or more dies 702 having integrated circuit structures formed on a surface of the wafer 700. The individual dies 702 may be a repeating unit of an integrated circuit product that includes any suitable integrated circuit. After the fabrication of the semiconductor product is complete, the wafer 700 may undergo a singulation process in which the dies 702 are separated from one another to provide discrete “chips” of the integrated circuit product. The die 702 may include one or more transistors (e.g., some of the transistors 840 of FIG. 8, discussed below), supporting circuitry to route electrical signals to the transistors, passive components (e.g., signal traces, resistors, capacitors, or inductors), and/or any other integrated circuit components. In some embodiments, the wafer 700 or the die 702 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 702. For example, a memory array formed by multiple memory devices may be formed on a same die 702 as a processor unit (e.g., the processor unit 902 of FIG. 9) or other logic that is configured to store information in the memory devices or execute instructions stored in the memory array.

FIG. 8 is a cross-sectional side view of an integrated circuit device 800 that may be included in any of the embodiments disclosed herein. One or more of the integrated circuit devices 800 may be included in one or more dies 702 (FIG. 7). The integrated circuit device 800 may be formed on a die substrate 802 (e.g., the wafer 700 of FIG. 7) and may be included in a die (e.g., the die 702 of FIG. 7). The die substrate 802 may be a semiconductor substrate composed of semiconductor material systems including, for example, n-type or p-type materials systems (or a combination of both). The die substrate 802 may include, for example, a crystalline substrate formed using a bulk silicon or a silicon-on-insulator (SOI) substructure. In some embodiments, the die substrate 802 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 802. Although a few examples of materials from which the die substrate 802 may be formed are described here, any material that may serve as a foundation for an integrated circuit device 800 may be used. The die substrate 802 may be part of a singulated die (e.g., the dies 702 of FIG. 7) or a wafer (e.g., the wafer 700 of FIG. 7).

The integrated circuit device 800 may include one or more device layers 804 disposed on the die substrate 802. The device layer 804 may include features of one or more transistors 840 (e.g., metal oxide semiconductor field-effect transistors (MOSFETs)) formed on the die substrate 802. The transistors 840 may include, for example, one or more source and/or drain (S/D) regions 820, a gate 822 to control current flow between the S/D regions 820, and one or more S/D contacts 824 to route electrical signals to/from the S/D regions 820. The transistors 840 may include additional features not depicted for the sake of clarity, such as device isolation regions, gate contacts, and the like. The transistors 840 are not limited to the type and configuration depicted in FIG. 8 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

Returning to FIG. 8, a transistor 840 may include a gate 822 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 840 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 840 along the source-channel-drain direction, the gate electrode may consist of a U-shaped structure that includes a bottom portion substantially parallel to the surface of the die substrate 802 and two sidewall portions that are substantially perpendicular to the top surface of the die substrate 802. In other embodiments, at least one of the metal layers that form the gate electrode may simply be a planar layer that is substantially parallel to the top surface of the die substrate 802 and does not include sidewall portions substantially perpendicular to the top surface of the die substrate 802. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 820 may be formed within the die substrate 802 adjacent to the gate 822 of individual transistors 840. The S/D regions 820 may be formed using an implantation/diffusion process or an etching/deposition process, for example. In the former process, dopants such as boron, aluminum, antimony, phosphorous, or arsenic may be ion-implanted into the die substrate 802 to form the S/D regions 820. An annealing process that activates the dopants and causes them to diffuse farther into the die substrate 802 may follow the ion-implantation process. In the latter process, the die substrate 802 may first be etched to form recesses at the locations of the S/D regions 820. An epitaxial deposition process may then be carried out to fill the recesses with material that is used to fabricate the S/D regions 820. In some implementations, the S/D regions 820 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 820 may be formed using one or more alternate semiconductor materials such as germanium or a group III-V material or alloy. In further embodiments, one or more layers of metal and/or metal alloys may be used to form the S/D regions 820.

Electrical signals, such as power and/or input/output (I/O) signals, may be routed to and/or from the devices (e.g., transistors 840) of the device layer 804 through one or more interconnect layers disposed on the device layer 804 (illustrated in FIG. 8 as interconnect layers 806-810). For example, electrically conductive features of the device layer 804 (e.g., the gate 822 and the S/D contacts 824) may be electrically coupled with the interconnect structures 828 of the interconnect layers 806-810. The one or more interconnect layers 806-810 may form a metallization stack (also referred to as an “ILD stack”) 819 of the integrated circuit device 800.

The interconnect structures 828 may be arranged within the interconnect layers 806-810 to route electrical signals according to a wide variety of designs; in particular, the arrangement is not limited to the particular configuration of interconnect structures 828 depicted in FIG. 8. Although a particular number of interconnect layers 806-810 is depicted in FIG. 8, embodiments of the present disclosure include integrated circuit devices having more or fewer interconnect layers than depicted.

In some embodiments, the interconnect structures 828 may include lines 828a and/or vias 828b filled with an electrically conductive material such as a metal. The lines 828a may be arranged to route electrical signals in a direction of a plane that is substantially parallel with a surface of the die substrate 802 upon which the device layer 804 is formed. For example, the lines 828a may route electrical signals in a direction in and out of the page and/or in a direction across the page from the perspective of FIG. 8. The vias 828b may be arranged to route electrical signals in a direction of a plane that is substantially perpendicular to the surface of the die substrate 802 upon which the device layer 804 is formed. In some embodiments, the vias 828b may electrically couple lines 828a of different interconnect layers 806-810 together.

The interconnect layers 806-810 may include a dielectric material 826 disposed between the interconnect structures 828, as shown in FIG. 8. In some embodiments, dielectric material 826 disposed between the interconnect structures 828 in different ones of the interconnect layers 806-810 may have different compositions; in other embodiments, the composition of the dielectric material 826 between different interconnect layers 806-810 may be the same. The device layer 804 may include a dielectric material 826 disposed between the transistors 840 and a bottom layer of the metallization stack as well. The dielectric material 826 included in the device layer 804 may have a different composition than the dielectric material 826 included in the interconnect layers 806-810; in other embodiments, the composition of the dielectric material 826 in the device layer 804 may be the same as a dielectric material 826 included in any one of the interconnect layers 806-810.

A first interconnect layer 806 (referred to as Metal 1 or “M1”) may be formed directly on the device layer 804. In some embodiments, the first interconnect layer 806 may include lines 828a and/or vias 828b, as shown. The lines 828a of the first interconnect layer 806 may be coupled with contacts (e.g., the S/D contacts 824) of the device layer 804. The vias 828b of the first interconnect layer 806 may be coupled with the lines 828a of a second interconnect layer 808.

The second interconnect layer 808 (referred to as Metal 2 or “M2”) may be formed directly on the first interconnect layer 806. In some embodiments, the second interconnect layer 808 may include via 828b to couple the lines 828 of the second interconnect layer 808 with the lines 828a of a third interconnect layer 810. Although the lines 828a and the vias 828b are structurally delineated with a line within individual interconnect layers for the sake of clarity, the lines 828a and the vias 828b may be structurally and/or materially contiguous (e.g., simultaneously filled during a dual-damascene process) in some embodiments.

The third interconnect layer 810 (referred to as Metal 3 or “M3”) (and additional interconnect layers, as desired) may be formed in succession on the second interconnect layer 808 according to similar techniques and configurations described in connection with the second interconnect layer 808 or the first interconnect layer 806. In some embodiments, the interconnect layers that are “higher up” in the metallization stack 819 in the integrated circuit device 800 (i.e., farther away from the device layer 804) may be thicker that the interconnect layers that are lower in the metallization stack 819, with lines 828a and vias 828b in the higher interconnect layers being thicker than those in the lower interconnect layers.

The integrated circuit device 800 may include a solder resist material 834 (e.g., polyimide or similar material) and one or more conductive contacts 836 formed on the interconnect layers 806-810. In FIG. 8, the conductive contacts 836 are illustrated as taking the form of bond pads. The conductive contacts 836 may be electrically coupled with the interconnect structures 828 and configured to route the electrical signals of the transistor(s) 840 to external devices. For example, solder bonds may be formed on the one or more conductive contacts 836 to mechanically and/or electrically couple an integrated circuit die including the integrated circuit device 800 with another component (e.g., a printed circuit board or a package substrate, e.g., 112). The integrated circuit device 800 may include additional or alternate structures to route the electrical signals from the interconnect layers 806-810; for example, the conductive contacts 836 may include other analogous features (e.g., posts) that route the electrical signals to external components.

In some embodiments in which the integrated circuit device 800 is a double-sided die, the integrated circuit device 800 may include another metallization stack (not shown) on the opposite side of the device layer(s) 804. This metallization stack may include multiple interconnect layers as discussed above with reference to the interconnect layers 806-810, to provide conductive pathways (e.g., including conductive lines and vias) between the device layer(s) 804 and additional conductive contacts (not shown) on the opposite side of the integrated circuit device 800 from the conductive contacts 836.

In other embodiments in which the integrated circuit device 800 is a double-sided die, the integrated circuit device 800 may include one or more through silicon vias (TSVs) through the die substrate 802; these TSVs may make contact with the device layer(s) 804, and may provide conductive pathways between the device layer(s) 804 and additional conductive contacts (not shown) on the opposite side of the integrated circuit device 800 from the conductive contacts 836. In some embodiments, TSVs extending through the substrate can be used for routing power and ground signals from conductive contacts on the opposite side of the integrated circuit device 800 from the conductive contacts 836 to the transistors 840 and any other components integrated into the die 800, and the metallization stack 819 can be used to route I/O signals from the conductive contacts 836 to transistors 840 and any other components integrated into the die 800.

Multiple integrated circuit devices 800 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

FIG. 9 is a block diagram of an example electrical device 900 that may include one or more of the embodiments disclosed herein. For example, any suitable ones of the components of the electrical device 900 may include one or more of assemblies 100, integrated circuit devices 800, or integrated circuit dies 702 disclosed herein. A number of components are illustrated in FIG. 9 as included in the electrical device 900, but any one or more of these components may be omitted or duplicated, as suitable for the application. In some embodiments, some or all of the components included in the electrical device 900 may be attached to one or more motherboards mainboards, or system boards. In some embodiments, one or more of these components are fabricated onto a single system-on-a-chip (SoC) die.

Additionally, in various embodiments, the electrical device 900 may not include one or more of the components illustrated in FIG. 9, but the electrical device 900 may include interface circuitry for coupling to the one or more components. For example, the electrical device 900 may not include a display device 906, but may include display device interface circuitry (e.g., a connector and driver circuitry) to which a display device 906 may be coupled. In another set of examples, the electrical device 900 may not include an audio input device 924 or an audio output device 908, but may include audio input or output device interface circuitry (e.g., connectors and supporting circuitry) to which an audio input device 924 or audio output device 908 may be coupled.

The electrical device 900 may include one or more processor units 902 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 902 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 900 may include a memory 904, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 904 may include memory that is located on the same integrated circuit die as the processor unit 902. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 900 can comprise one or more processor units 902 that are heterogeneous or asymmetric to another processor unit 902 in the electrical device 900. There can be a variety of differences between the processing units 902 in a system in terms of a spectrum of metrics of merit including architectural, microarchitectural, thermal, power consumption characteristics, and the like. These differences can effectively manifest themselves as asymmetry and heterogeneity among the processor units 902 in the electrical device 900.

In some embodiments, the electrical device 900 may include a communication component 912 (e.g., one or more communication components). For example, the communication component 912 can manage wireless communications for the transfer of data to and from the electrical device 900. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 912 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 912 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 912 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 912 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 912 may operate in accordance with other wireless protocols in other embodiments. The electrical device 900 may include an antenna 922 to facilitate wireless communications and/or to receive other wireless communications (such as AM or FM radio transmissions).

In some embodiments, the communication component 912 may manage wired communications, such as electrical, optical, or any other suitable communication protocols (e.g., IEEE 802.3 Ethernet standards). As noted above, the communication component 912 may include multiple communication components. For instance, a first communication component 912 may be dedicated to shorter-range wireless communications such as Wi-Fi or Bluetooth, and a second communication component 912 may be dedicated to longer-range wireless communications such as global positioning system (GPS), EDGE, GPRS, CDMA, WiMAX, LTE, EV-DO, or others. In some embodiments, a first communication component 912 may be dedicated to wireless communications, and a second communication component 912 may be dedicated to wired communications.

The electrical device 900 may include battery/power circuitry 914. The battery/power circuitry 914 may include one or more energy storage devices (e.g., batteries or capacitors) and/or circuitry for coupling components of the electrical device 900 to an energy source separate from the electrical device 900 (e.g., AC line power).

The electrical device 900 may include a display device 906 (or corresponding interface circuitry, as discussed above). The display device 906 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 900 may include an audio output device 908 (or corresponding interface circuitry, as discussed above). The audio output device 908 may include any embedded or wired or wirelessly connected external device that generates an audible indicator, such speakers, headsets, or earbuds.

The electrical device 900 may include an audio input device 924 (or corresponding interface circuitry, as discussed above). The audio input device 924 may include any embedded or wired or wirelessly connected device that generates a signal representative of a sound, such as microphones, microphone arrays, or digital instruments (e.g., instruments having a musical instrument digital interface (MIDI) output). The electrical device 900 may include a Global Navigation Satellite System (GNSS) device 918 (or corresponding interface circuitry, as discussed above), such as a Global Positioning System (GPS) device. The GNSS device 918 may be in communication with a satellite-based system and may determine a geolocation of the electrical device 900 based on information received from one or more GNSS satellites, as known in the art.

The electrical device 900 may include another output device 910 (or corresponding interface circuitry, as discussed above). Examples of the other output device 910 may include an audio codec, a video codec, a printer, a wired or wireless transmitter for providing information to other devices, or an additional storage device.

The electrical device 900 may include another input device 920 (or corresponding interface circuitry, as discussed above). Examples of the other input device 920 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 900 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 900 may be any other electronic device that processes data. In some embodiments, the electrical device 900 may comprise multiple discrete physical components. Given the range of devices that the electrical device 900 can be manifested as in various embodiments, in some embodiments, the electrical device 900 can be referred to as a computing device or a computing system.

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 is an integrated circuit apparatus comprising: an integrated circuit die; and a package substrate comprising circuitry to interconnect the integrated circuit die with a main circuit board; wherein the integrated circuit die is coupled to a first side of the package substrate and a second side of the package substrate opposite the first side comprises a plurality of electrical connectors arranged in a hexagonal array pattern, wherein a distance between a connector and its neighboring connectors in a first direction is less than a distance between the connector and its other neighboring connectors.

Example 2 includes the subject matter of Example 1, wherein respective pairs of the electrical connectors are connected to corresponding differential pairs of the integrated circuit, and the pairs of electrical circuits are arranged in the first direction.

Example 3 includes the subject matter of Example 2, wherein the differential pairs are high-speed input/output connections for the integrated circuit.

Example 4 includes the subject matter of Example 2 or 3, wherein the hexagonal array pattern has a signal to ground ratio of 1:1.5.

Example 5 includes the subject matter of Example 2 or 3, wherein the hexagonal array pattern has a signal to ground ratio of 1:2.

Example 6 includes the subject matter of any one of Examples 1-5, wherein the hexagonal array pattern defines a hexagonal pattern of neighboring connectors surrounding each electrical connector.

Example 7 is an integrated circuit apparatus comprising: an integrated circuit die; and a package substrate comprising circuitry to interconnect the integrated circuit die with a main circuit board; wherein the integrated circuit die is coupled to a first side of the package substrate and a second side of the package substrate opposite the first side comprises a plurality of electrical connectors arranged in an array of rows and columns, wherein a distance between a connector and its neighboring connectors in its column is less than a distance between the connector and its neighboring connectors in its row.

Example 8 includes the subject matter of Example 7, wherein respective pairs of the electrical connectors are connected to corresponding differential pairs of the integrated circuit, and the pairs of electrical circuits are arranged in the column direction.

Example 9 includes the subject matter of Example 8, wherein the differential pairs are high-speed input/output connections for the integrated circuit.

Example 10 includes the subject matter of Example 8 or 9, wherein a first pair of electrical connectors corresponding to a first differential pair is arranged at a distance of 1.5 pins from a second pair of electrical connectors corresponding to a second differential pair.

Example 11 includes the subject matter of Example 8 or 9, wherein a first pair of electrical connectors corresponding to a first differential pair is arranged at a distance of 2 pins from a second pair of electrical connectors corresponding to a second differential pair.

Example 12 is a system comprising: a main circuit board; and a package coupled to the main circuit board, the package comprising: an integrated circuit die; and a package substrate comprising circuitry to interconnect the integrated circuit die with the main circuit board; wherein the integrated circuit die is coupled to a first side of the package substrate and a second side of the package substrate opposite the first side comprises a plurality of electrical connectors arranged in a compressed array pattern, wherein a distance between a connector and its neighboring connectors in a direction of compression is less than a distance between the connector and its neighboring connectors in other directions.

Example 13 includes the subject matter of Example 12, wherein the array pattern is a hexagonal array pattern.

Example 14 includes the subject matter of Example 12, wherein the array pattern is a rectangular array pattern.

Example 15 includes the subject matter of any one of Examples 12-14, wherein the array pattern comprises sets of differential pair connections for the integrated circuit, and the differential pair connections are arranged in the direction of compression.

Example 16 includes the subject matter of Example 15, wherein at least certain of the differential pair connections are high-speed input/output connections for the integrated circuit.

Example 17 includes the subject matter of Example 16, wherein at least certain of the differential pair connections are Peripheral Component Interconnect Express (PCIe) connections for the integrated circuit.

Example 18 includes the subject matter of Example 16 or 17, wherein the main circuit board comprises a set of differential pairs arranged in two rows, the set of differential pairs connected to respective traces on the same layer of the main circuit board.

Example 19 includes the subject matter of any one of Examples 12-18, wherein the main circuit board is a motherboard and the integrated circuit die comprises a processor.

Example 20 includes the subject matter of any one of Examples 12-19, further comprising a socket coupled to the main circuit board, the socket comprising a set of pins to interconnect the package and the main circuit board.

In the above description, various aspects of the illustrative implementations have been described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials, and configurations have been set forth to provide a thorough understanding of the illustrative implementations. However, it will be apparent to one skilled in the art that the present disclosure may be practiced without all of the specific details. In other instances, well-known features have been omitted or simplified in order not to obscure the illustrative implementations.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The terms “over,” “under,” “between,” “above,” and “on” as used herein may refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features.

The above description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated.

1. An integrated circuit apparatus comprising:
an integrated circuit die; and
a package substrate comprising circuitry to interconnect the integrated circuit die with a main circuit board;
wherein the integrated circuit die is coupled to a first side of the package substrate and a second side of the package substrate opposite the first side comprises a plurality of electrical connectors arranged in a hexagonal array pattern, wherein a distance between a connector and its neighboring connectors in a first direction is less than a distance between the connector and its other neighboring connectors.

2. The apparatus of claim 1, wherein respective pairs of the electrical connectors are connected to corresponding differential pairs of the integrated circuit, and the pairs of electrical circuits are arranged in the first direction.

3. The apparatus of claim 2, wherein the differential pairs are high-speed input/output connections for the integrated circuit.

4. The apparatus of claim 2, wherein the hexagonal array pattern has a signal to ground ratio of 1:1.5.

5. The apparatus of claim 2, wherein the hexagonal array pattern has a signal to ground ratio of 1:2.

6. The apparatus of claim 1, wherein the hexagonal array pattern defines a hexagonal pattern of neighboring connectors surrounding each electrical connector.

7. An integrated circuit apparatus comprising:
an integrated circuit die; and
a package substrate comprising circuitry to interconnect the integrated circuit die with a main circuit board;
wherein the integrated circuit die is coupled to a first side of the package substrate and a second side of the package substrate opposite the first side comprises a plurality of electrical connectors arranged in an array of rows and columns, wherein a distance between a connector and its neighboring connectors in its column is less than a distance between the connector and its neighboring connectors in its row.

8. The apparatus of claim 7, wherein respective pairs of the electrical connectors are connected to corresponding differential pairs of the integrated circuit, and the pairs of electrical circuits are arranged in the column direction.

9. The apparatus of claim 8, wherein the differential pairs are high-speed input/output connections for the integrated circuit.

10. The apparatus of claim 8, wherein a first pair of electrical connectors corresponding to a first differential pair is arranged at a distance of 1.5 pins from a second pair of electrical connectors corresponding to a second differential pair.

11. The apparatus of claim 8, wherein a first pair of electrical connectors corresponding to a first differential pair is arranged at a distance of 2 pins from a second pair of electrical connectors corresponding to a second differential pair.

12. A system comprising:
a main circuit board; and
a package coupled to the main circuit board, the package comprising:
an integrated circuit die; and
a package substrate comprising circuitry to interconnect the integrated circuit die with the main circuit board;
wherein the integrated circuit die is coupled to a first side of the package substrate and a second side of the package substrate opposite the first side comprises a plurality of electrical connectors arranged in a compressed array pattern, wherein a distance between a connector and its neighboring connectors in a direction of compression is less than a distance between the connector and its neighboring connectors in other directions.

13. The system of claim 12, wherein the array pattern is a hexagonal array pattern.

14. The system of claim 12, wherein the array pattern is a rectangular array pattern.

15. The system of claim 12, wherein the array pattern comprises sets of differential pair connections for the integrated circuit, and the differential pair connections are arranged in the direction of compression.

16. The system of claim 15, wherein at least certain of the differential pair connections are high-speed input/output connections for the integrated circuit.

17. The system of claim 16, wherein at least certain of the differential pair connections are Peripheral Component Interconnect Express (PCIe) connections for the integrated circuit.

18. The system of claim 16, wherein the main circuit board comprises a set of differential pairs arranged in two rows, the set of differential pairs connected to respective traces on the same layer of the main circuit board.

19. The system of claim 12, wherein the main circuit board is a motherboard and the integrated circuit die comprises a processor.

20. The system of claim 12, further comprising a socket coupled to the main circuit board, the socket comprising a set of pins to interconnect the package and the main circuit board.
